(19) United States
(12) Patent Application Publication
(10) Pub. No.: US 2005/0083766 A1
(43) Pub. Date: Apr. 21, 2005

(54) Random access memory having self-adjusting off-chip driver

(75) Inventors: Jung Pill Kim, Cary, NC (US); Jonghee Han, Cary, NC (US)

Correspondence Address: Dicke, Billig & Czaja, PLLC;Suite 2250, Fifth Street Towers, 100 South Fifth Street, Minneapolis, MN, 55402, US

(73) Assignee: Infineon Technologies North America Corp.

(21) Appl. No.: 10/690,358

(22) Filed: Oct. 21, 2003

(51) Int. Cl. G11C 11/24

(52) U.S. Cl. 365/230.05

(57) ABSTRACT

One embodiment of the present invention provides a random access memory device including a memory array, a level detector, and an off-chip driver circuit. The level detector monitors a source voltage and provides a level signal representative of a voltage range of the source voltage. The off-chip driver circuit is associated with the memory array and provides an output signal having at least one operating parameter, and adjusts the at least one operating parameter by adjusting a magnitude of at least one impedance based on the level signal.

### BACKGROUND

Off-chip driver (OCD) circuits are employed by semiconductor devices, including dynamic random access memory (DRAM) devices, to provide off-chip interfacing to external buses or external devices. The OCD circuits are generally required to provide an output signal that meets specified operating parameters of the external device. For example, OCD circuits are generally required to provide an output signal having a signal strength that is within a specified current range and a slew rate that is within a specified range of voltage rates.

The signal strength and slew rate are affected by many factors such as voltage variation of an OCD supply voltage (VDDQ), process variations, variations in operating temperature, and even data patterns. Regarding signal strength, the most significant factor is variations in the magnitude of VDDQ. If VDDQ is too high or too low, the output signal strength may respectively exceed or fall below the specified operating range. The largest factor affecting slew rate is the AC transient operation of the OCD circuit, which is in-turn dependent VDDQ. If VDDQ is too high or too low, the slew rate may respectively exceed or fall below a specified slew rate range.

Generally, an OCD circuit is designed during the final stages of development of a DRAM device. However, due to the various factors that can impact the signal strength and slew rate, it can be difficult to design an OCD circuit that meets specified operating parameters and often leads to costly delays in the fabrication and mass-production of the DRAM device.

### SUMMARY

One embodiment of the present invention provides a random access memory device including a memory array, a level detector, and an off-chip driver circuit. The level detector monitors a source voltage and provides a level signal representative of a voltage range of the source voltage. The off-chip driver circuit is associated with the memory array and provides an output signal having at least one operating parameter, and adjusts the at least one operating parameter by adjusting a magnitude of at least one impedance based on the level signal.

### BRIEF DESCRIPTION OF THE DRAWINGS

FIG. 1 is a block diagram illustrating generally one exemplary embodiment of dynamic random access memory device according to the present invention.

FIG. 2 is a schematic diagram illustrating one exemplary embodiment of level detector according to the present invention

FIG. 3A is a schematic block diagram illustrating one exemplary embodiment of an off-chip driver circuit according to the present invention

FIG. 3B is a schematic diagram illustrating one exemplary embodiment of pull-up pre-driver circuit according to the present invention for use with the off-chip driver circuit of FIG. 3A.

FIG. 3C is a schematic diagram illustrating one exemplary embodiment of pull-down pre-driver circuit according to the present invention for use with the off-chip driver circuit of FIG. 3A.

FIG. 4A is a schematic block diagram illustrating one exemplary embodiment of an off-chip driver circuit according to the present invention

FIG. 4B is a schematic diagram illustrating one exemplary embodiment of pull-up pre-driver circuit according to the present invention for use with the off-chip driver circuit of FIG. 4A.

FIG. 4C is a schematic diagram illustrating one exemplary embodiment of pull-down pre-driver circuit according to the present invention for use with the off-chip driver circuit of FIG. 4A.

### DETAILED DESCRIPTION

In the following Detailed Description, reference is made to the accompanying drawings which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

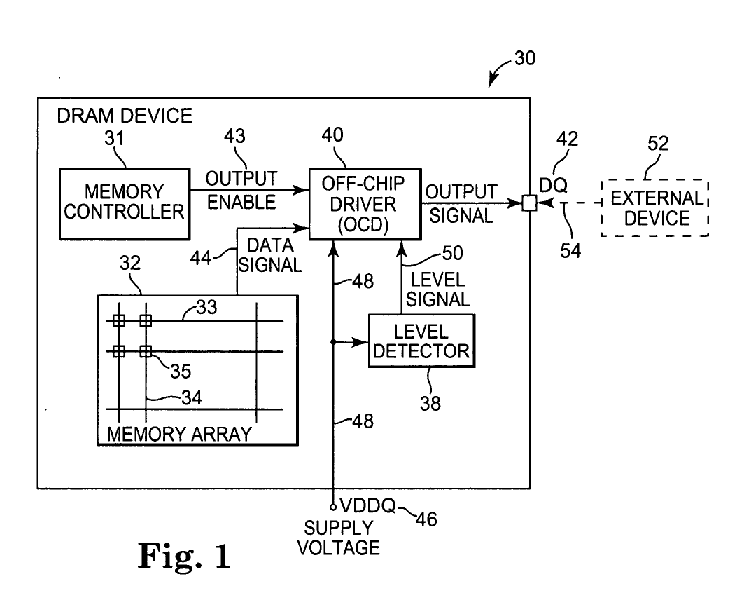

FIG. 1 is a block diagram illustrating generally one exemplary embodiment of a device 30 according to the present invention. In one embodiment, memory device 30 is a random access memory device (RAM), and in one preferred embodiment, is a dynamic random access memory device (DRAM). DRAM device 30 includes a memory controller 31, an array of memory cells 32, a level detector 38, an off-chip driver (OCD) circuit 40, and an output pad, or pin (DQ) 42. Conductive wordlines 33, sometimes referred to as row select lines, extend in the x-direction across memory array 32, while conductive bit lines 34, sometimes referred to as column select lines, extend in the y-direction. A memory cell 35 is located at each intersection of a wordline 33 and bit line 34.

OCD circuit 40 receives an output enable (OE) signal from memory controller 31 via a path 43 and a data signal representative of data stored in memory array 32 via a path 44, and is coupled to a supply voltage (VDDQ) 46 via a path 48. Level detector 38 is coupled to VDDQ 46 at 48 and provides a level signal representative of a voltage range of VDDQ 46 to OCD circuit 40 via a path 50. OCD circuit 40, in response to the OE signal at 43 and the data signal from memory array 32 at 44, provides an output signal representative of the stored data at DQ 42, wherein the output signal has at least one operating parameter. OCD circuit 40 adjusts the operating parameter based on level signal received from level detector 38 via path 50.

By adjusting the operating parameter of the output signal based on the level signal, OCD circuit 40 is able to maintain the operating parameter within a specified range required by an external device 52 receiving the output signal at DQ 42 via a path 54. In one embodiment, the operating parameter comprises an output current, or signal strength of the output signal. In one embodiment, the operating parameter comprises a rate of change of an output voltage over time, or slew rate, of the output signal.

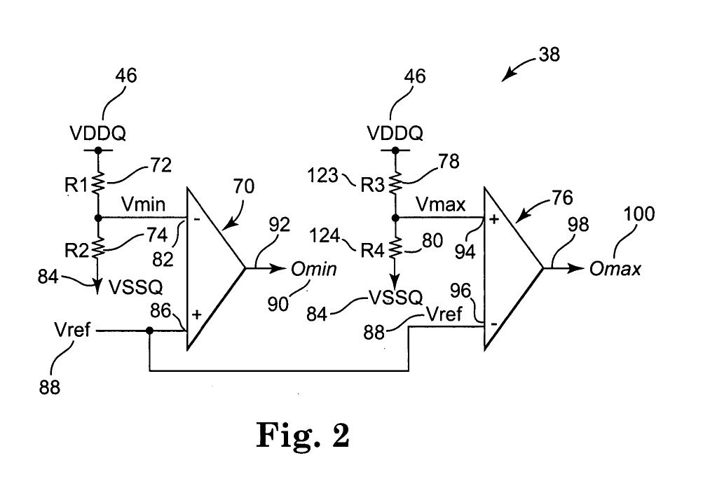

FIG. 2 is a schematic block diagram illustrating one exemplary embodiment of level detector 38 according to the present invention configured to provide indication of when VDDQ 46 is above, below, or within a voltage range. In the illustrated embodiment, level detector 38 includes a first comparator 70, a first resistor (R1) 72, a second resistor (R2) 74, a second comparator 76, a third resistor (R3) 78, and a fourth resistor (R4) 80.

R1 72 has a first terminal coupled to VDDQ 46, and a second terminal coupled to an inverting terminal 82 of comparator 70. R2 74 has a first terminal coupled to inverting terminal 82 and a second terminal coupled to a reference node (VSSQ) 84. In one embodiment, VSSQ 84 is a negative source voltage. In one embodiment, VSSQ 84 is a ground node. A non-inverting terminal 86 of comparator 70 is coupled to a substantially constant reference voltage (Vref). R1 72 and R2 74 function as a voltage divider with the voltage across R2 74 providing the minimum voltage level (Vmin) of the voltage range at inverting terminal 82. When Vmin at inverting terminal 82 drops below Vref 88 at non-inverting terminal 86, comparator 70 provides a first level signal (Omin) 90 having a “high” level (i.e., “1”) at an output 92. When Vmin at inverting terminal 82 is greater than or equal to Vref 88, Omin 90 has a “low” level (i.e., “0”).

R3 78 has a first terminal coupled to VDDQ 46, and a second terminal coupled to an inverting terminal 94 of comparator 76. R4 80 has a first terminal coupled to inverting terminal 94 and a second terminal coupled to VSSQ 84. A non-inverting terminal 96 of comparator 70 is coupled to Vref 88. R3 78 and R4 80 function as a voltage divider with the voltage across R4 80 providing the maximum voltage level (Vmax) of the voltage range at inverting terminal 94. When Vmax at inverting terminal 96 rises above Vref at non-inverting terminal 96, comparator 76 provides at an output 98 a second level signal (Omax) 100 having a “high” level (i.e., “1”). When Vmax at inverting terminal 94 is less than or equal to Vref 88, Omax 100 has a “low” level (i.e., “0”).

As an illustrative example, assume that R1 72 comprises 48% and R2 74 comprises 52% of the sum of R1 72 and R2 74. Also assume that R3 78 is equal to R2 74, that R4 80 is equal to R1 72, and that Vref 88 has a substantially constant value of 1.25 volts. Using these values, Omin 90 has a “high” level when VDDQ drops below approximately 2.4 volts and Omax 100 has a “high” level when VDDQ rises above approximately 2.6 volts. Omin 90 and Omax 100 each have a “low” level when VDDQ is at or between 2.4 and 2.6 volts.

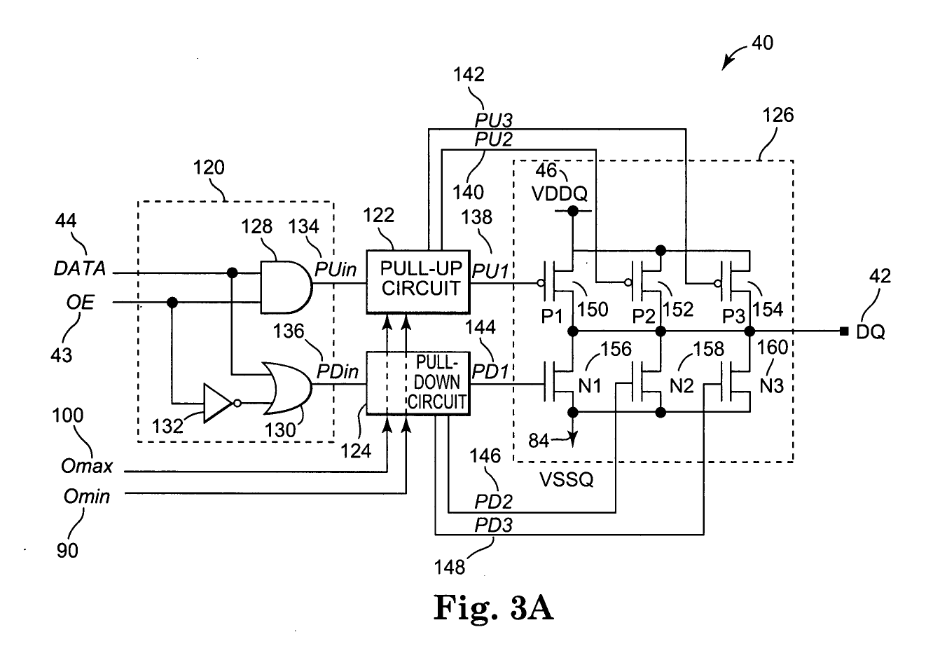

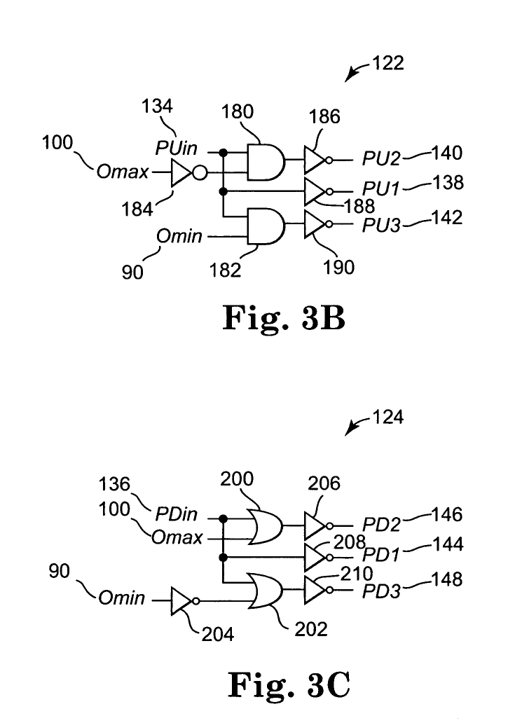

FIG. 3A is a schematic block diagram illustrating one exemplary embodiment of OCD circuit 40 according to the present invention configured to adjust the signal strength, or output current, of the output signal provided at DQ 42. OCD circuit 40 includes a logic circuit 120, a pull-up pre-driver circuit 122, a pull-down pre-driver circuit 124, and an output driver circuit 126.

Logic circuit 120 further includes an AND-gate 128, an OR-gate 130, and an inverter 132. AND-gate 128 receives data signal 48 at a first input and OE 44 at a second input, and provides a pull-up enable signal (PUin) 134 at an output. OR-gate 130 receives data signal 46 at a first input and OE 44 via inverter 132 at a second gate, and provides a pull-down enable signal (PDin) 136 at an output. PUin 134 has a “high” level when OE 44 has a “high” level and data signal 44 has a “high” level, and a “low” level when OE 44 has a “high” level and data signal 44 has a “low” level. PDin 136 has a “high” level

Pull-up pre-driver circuit 122 receives PUin 134 from logic circuit 120 and Omin 90 and Omax 100 from level detector 38, and provides a first pull-up signal (PU1) 138, a second pull-up signal (PU2) 140, and a third pull-up signal (PU3) 142. Pull-down pre-driver circuit 124 receives PDin 136 from logic circuit 120 and Omin 90 and Omax 100 from level detector 38, and provides first pull-down signal (PD1) 144, second pull-down signal (PD2) 146, and third pull-down signal (PD3) 148.

Output driver circuit 126 includes PMOS switches P1 150, P2 152, P3 154, and NMOS switches N1 156, N2 158, and N3 160. The gates of P1 150, P2 152, and P3 154 respectively receive PU1 138, PU2 140, and PU3 142 from pull-up pre-driver circuit 122. The sources and drains of P1 150, P2 152, and P3 154 are respectively coupled to VDDQ 46 and DQ 42. The gates of N1 156, N2 158, and N3 160 respectively receive PD1 144, PD2 146, and PD3 148. The drains and sources of N1 156, N2 158, and N3 160 are respectively coupled to DQ 42 and VSSQ 84.

When both OE 44 and data signal 46 are “high”, pull-down circuit 124 turns-off NMOS switches N1 156, N2 158, and N3 160 to isolate DQ 42 from VSSQ 84, and pull-up circuit 122 controls PMOS switches P1 150, P2 152, and P3 154 based on the levels of Omin 90 and Omax 100. When both Omin 90 and Omax 100 are “low”, meaning VDDQ 46 is within a desired voltage range, pull-up circuit 122 turns-on P1 150 and P2 152 to connect DQ 42 to VDDQ 46 and thereby provide an output signal having an output current at DQ 42. When Omin is “high”, meaning VDDQ 38 is below the desired voltage range, pull-up circuit 122 also turns-on P3 154 to reduce the impedance between DQ 42 and VDDQ 46, thereby increasing the output current, and thus the output signal strength, at DQ 42. When Omax is “high”, meaning VDDQ 46 is above the desired voltage range, pull-up circuit 122 turns-off P2 152 leaving only P1 150 turned-on. This increases the impedance between DQ 42 and VDDQ 46, thereby decreasing the output current, and thus the output signal strength, at DQ 42.

When OE 44 is “high” and data signal 46 is “low”, pull-up circuit 124 turns-off PMOS switches P1 150, P2 152, and P3 154 to isolate DQ 42 from VDDQ 46, and pull-down circuit 124 controls NMOS switches N1 156, N2 158, and N3 160 based on the states of Omin 90 and Omax 100. When both Omin 90 and Omax 100 are “low”, meaning VDDQ 46 is within the desired voltage range, pull-down circuit turns-on NMOS switches N1 156 and N2 158 to connect DQ 42 to VSSQ 84 and thereby provide an output signal having an “output” current at DQ 42. When Omin is “high”, meaning that VDDQ 38 is below the desired voltage range, pull-down circuit 124 also turn-on NMOS switch 160. This decreases the impedance between DQ 42 and VSSQ 84, thereby increasing the “output” current by increasing the current sinking ability to VSSQ 84. When Omax is “high”, meaning that VDDQ 38 is above the desired voltage range, pull-down circuit 124 turns-off NMOS switches 158 and 160, leaving only NMOS switch 156 turned-on. This increases the impedance between DQ 42 and VSSQ 84, thereby decreasing the “output” current by decreasing the current sinking ability to VSSQ 84.

When OE 44 is “low”, meaning the output of OCD circuit 40 is disabled, pull-up circuit 122 turns-off PMOS switches P1 150, P2 152, and P3 154, and pull-down circuit 124 turns-off NMOS switches N1 156, N2 158, and N3 160 to thereby isolate DQ 42 from both VDDQ 46 and VSSQ 84.

FIG. 3B is a schematic diagram illustrating one exemplary embodiment of pull-up pre-driver circuit 122 according to the present invention as employed by OCD circuit 40 of FIG. 3A. In the illustrated embodiment, pull-up pre-driver circuit 122 includes AND-gates 180 and 182, and inverters 184, 186, 188, and 190. Inverter 188 receives PUin 134 at an input and provides PU1 138 at an output. AND-gate 180 receives PUin 134 at a first input and Omax 100 at a second input via inverter 100, and provides PU2 140 at an output via inverter 186. AND-gate 182 receives PUin 134 at a first input and Omin 90 at a second input and provides PU3 142 at an output via inverter 190.

When PUin 134 has a “low” level, PU1 138, PU2 140, and PU3 142 each have a “high” level, causing PMOS switches P1 150, P2 152, and P3 154 to be turned-off. When PUin 134 has a “high” level, the levels of PU1 138, PU2 140, and PU3 142 are based on the levels of Omin 90 and Omax 100. When Omin 90 and Omax 100 are both “low”, PU1 138 and PU2 140 are “low” and PU3 142 are “high”, resulting in PMOS switches P1 150 and P2 152 being turned-on and P3 154 being turned-off. When Omin 90 is “high” and Omax 100 is “low”, PU1 138, PU2 140, and PU3 142 each have a “low” level, causing PMOS switches P1 150, P2 152, and P3 154 to be turned-on. When Omin 90 is “low” and Omax 100 is “high”, PU1 138 is “low” and PU2 140 and PU3 142 are “high”, causing PMOS switch P1 150 is turned-on and PMOS switches P2 152 and P3 154 are turned-off.

FIG. 3C is a schematic diagram illustrating one exemplary embodiment of pull-down pre-driver circuit 124 according to the present invention as employed by OCD circuit 40 of FIG. 3A. In the illustrated embodiment, pull-down pre-driver circuit 124 includes OR-gates 200 and 202, and inverters 204, 206, 208, and 210. Inverter 208 receives PDin 136 at an input and provides PD1 133 at an output. OR-gate 200 receives PDin 136 at a first input and Omax 100 at a second input, and provides PD2 146 at an output via inverter 206. OR-gate 202 receives PDin 136 at a first input and Omin 90 via inverter 204 at a second input, and provides PD3 148 at an output via inverter 210.

When PDin 136 has a “high” level, PD1 144, PD2 146, and PD3 148 each have a “low” level, causing NMOS switches N1 156, N2 158, and N3 160 to be turned-off. When PDin 136 has a “low” level, the levels of PD1 144, PD2 146, and PD3 148 are based on the levels of Omin 90 and Omax 100. When Omin 90 and Omax 100 are both “low”, PD1 144 and PD2 146 are “high” and PD3 148 is “low” , causing NMOS switches N1 156 and N2 158 to be turned-on and switch N3 160 to be turned-off. When Omin 90 is “high” and Omax 100 is “low”, PD1 144, PD2 146, and PD3 148 each have a “high” level, causing NMOS switches N1 156, N2 158, and N3 160 to be turned-on. When Omin 90 is “low” and Omax 100 is “high”, PD1 144 has a “high” level and PD2 146 and PD3 148 each have a “low” level, causing NMOS switch N1 156 to be turned-on and NMOS switches N2 158 and N3 160 to be turned-off.

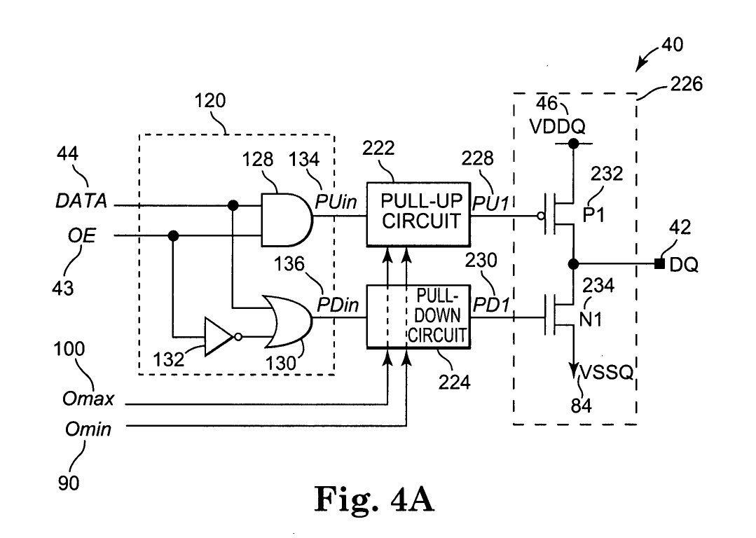

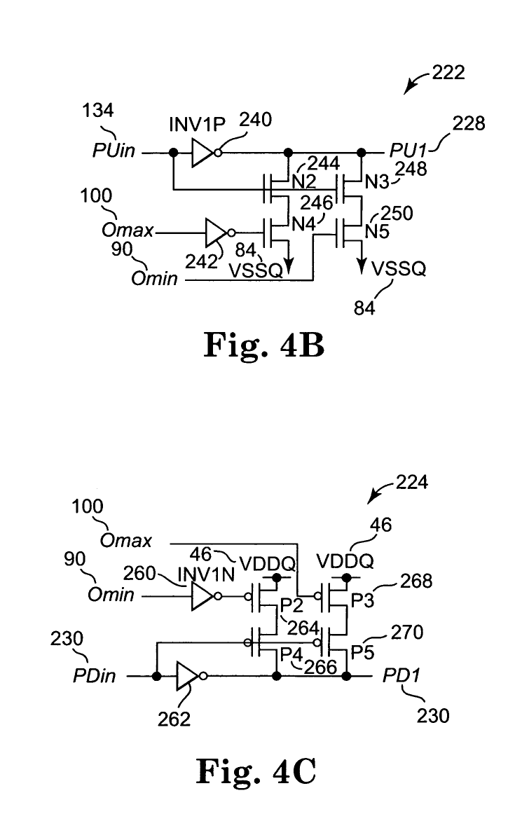

FIG. 4A is a schematic block diagram illustrating one exemplary embodiment of OCD circuit 40 according to the present invention configured to adjust the slew rate of the output signal provided at DQ 42. OCD circuit 40 includes logic circuit 120, a pull-up pre-driver circuit 222, a pull-down pre-driver circuit 224, and an output driver circuit 226.

Pull-up pre-driver circuit 222 receives PUin 134 from logic circuit 120 and Omin 90 and Omax 100 from level detector 38, and provides a pull-up signal PU1 228. Pull-down pre-driver circuit 224 receives PDin 136 from logic circuit 120 and Omin 90 and Omax 100 from level dectector 38, and provides a pull-down signal PD1 230.

Output driver circuit 226 includes a PMOS switch P1 232 and an NMOS switch N1 234. P1 232 receives PU1 228 at a gate, has a source coupled to VDDQ 46, and has a drain coupled to DQ 42. N1 234 receives PD1 230 at a gate, has a drain coupled to DQ 42, and a source coupled to VSSQ 84.

When both OE 44 and data signal 46 are “high”, pull-down circuit 224 turns-off N1 234 to isolate DQ 42 from VSSQ 84, and pull-up circuit 222 controls the current at the gate of P1 232 based on the levels of Omin 90 and Omax 100. When Omin 90 is “high”, meaning VDDQ is below a desired voltage range, pull-up pre-driver circuit 122 increases the current at the gate of P1 232 to increase the slew-rate. When Omax 100 is “high”, meaning VDDQ is above the desired voltage range, pull-up pre-driver circuit 222 decreases the current at the gate of P1 232 to decrease the slew-rate. When both Omin 90 and Omax 100 are “low”, pull-up pre-driver circuit 222 does not adjust the current at the gate of P1 232.

When OE 44 is “high” and data signal 46 is “low”, pull-up circuit 222 turns-off P1 232 to isolate DQ 42 from VDDQ 46, and pull-down circuit 224 controls the current at the gate of N1 234 based on the levels of Omin 90 and Omax 100. When Omin 90 is “high”, meaning VDDQ is below the desired voltage range, pull-down pre-driver circuit 224 increases the current at the gate of N1 234 to increase the slew rate. When Omax 100 is “high”, meaning that VDDQ is above the desired voltage range, pull-down circuit 224 decreases the current at the gate of N1 234 to decrease the slew rate. When both Omin 90 and Omax 100 are “low”, pull-down pre-driver circuit 224 does not adjust the current at the gate of N1 234.

When OE 44 is “low”, pull-up pre-driver circuit 222 turns-off P1 232 and pull-down pre-driver circuit 224 turns-off N1 234 to isolate DQ 42 from VDDQ 46 and VSSQ 84.

FIG. 4B is a schematic diagram illustrating one exemplary embodiment of pull-up pre-driver circuit 222 according to the present invention as employed by OCD circuit 40 of FIG. 4A. In the illustrated embodiment, pull-up pre-driver 222 includes inverters 240 and 242, and NMOS switches N2 244, N4 246, N3 248, and N5 250. Inverter 240 receives PUin 134 at an input and provides PU1 228 at an output. NMOS switch 244 receives PUin 134 at a gate, has a drain coupled to the output of inverter 240, and has a source. NMOS switch N3 248 receives PUin 134 at a gate, has a drain coupled to the output of inverter 240 and has a source. NMOS switch N4 246 receives Omax 100 via inverter 242 at a gate, has a drain coupled to the source of NMOS switch N2 244, and a source coupled to VSSQ 84. NMOS switch N5 250 receives Omin 90 at a gate, has a drain coupled to the source of NMOS switch 248, and a drain coupled to VSSQ 84.

When PUin 134 is “low” PU1 is high, causing P1 232 to be turned-off. Additionally, N2 244 and N3 248 are turned-off, causing the gate of P1 232 to be isolated from VSSQ 84.

When PUin 134 is “high”, switch P1 232 is turned-on and NMOS switches N2 244, N4 246, N3 248, and N5 250 are turned-on and -off based on the levels of Omin 90 and Omax 100. When Omin 90 and Omax 100 are “low”, meaning that VDDQ 46 is within the specified voltage range, switches N1 244, N2 246, and N3 248 are turned-on and N5 250 is turned-off, causing the gate of P1 232 to be coupled to VSSQ 84 through N2 244 and N4 246.

When Omin 90 is “high” and Omax 100 is “low”, meaning that VDDQ is below the specified voltage range, switch N5 250 is also turned-on. As a result, the impedance between the gate of P1 232 and VSSQ 84 is reduced, thereby increasing the rate at which P1 232 is turned-on and increasing the output signal slew-rate at DQ 42. When Omin 90 is “low” and Omax 100 is “high”, meaning that VDDQ is above the specified voltage range, switches N4 246 and N5 250 are turned-off. As a result, the gate of P1 232 is isolated from VSSQ 84, thereby decreasing the rate at which P1 232 is turned-on and decreasing the output signal slew rate at DQ 42.

FIG. 4C is a schematic diagram illustrating one exemplary embodiment of pull-down pre-driver circuit 224 according to the present invention as employed by OCD circuit 40 of FIG. 4A. In the illustrated embodiment, pull-down pre-driver circuit 224 includes inverters 260 and 262, and PMOS switches P2 264, P4 266, P3 268, and P5 270. Inverter 262 receives PDin 230 at an input and provides PD1 230 at an output. PMOS switch P4 266 receives PDin 230 at a gate, has a drain coupled to the output of inverter 262, and has a source. PMOS switch P5 270 receives PDin 230 at a gate, has a drain coupled to the output of inverter 262, and has a source. PMOS switch P2 264 receives Omin 90 via inverter 260 at a gate, has a drain coupled to the source of PMOS switch P4 266, and a source coupled to VDDQ 46. PMOS switch P3 268 receives Omax 100 at a gate, has a drain coupled to the source of PMOS switch P5, and a source coupled to VDDQ 46.

When PDin 230 is “high” PD1 is “low”, causing N1 234 to be turned-off. Additionally, switches P4 266 and P5 270 are turned-off, causing the gate of N1 234 to be isolated from VDDQ 46.

When PDin 230 is “low”, switch N1 234 is turned-on and PMOS switches P2 264, P3 268, P4 266, and P5 270 are turned-on and -off based on the levels of Omin 90 and Omax 100. When Omin 90 and Omax 100 are “low”, meaning that VDDQ 46 is within the specified voltage range, switches P3 268, P4 266, and P5 270 are turned-on and P2 264 is turned-off, causing the gate of N1 234 to be pulled to VDDQ 46 through P3 268 and P4 270 P1 to be turn-on.

When Omin 90 is “high” and Omax 100 is “low”, meaning that VDDQ is below the specified voltage range, switch P2 264 is also turned-on. As a result, the impedance between the gate of N1 234 and VDDQ 46 is reduced, thereby increasing the rate at which N1 234 is turned-on and increasing the output signal slew-rate at DQ 42. When Omin 90 is “low” and Omax 100 is “high”, meaning that VDDQ is above the specified voltage range, switches P2 264 and P3 268 are turned-off. As a result, the gate of N1 234 is isolated from VDDQ 84, thereby decreasing the rate at which N1 234 is turned-on and decreasing the output signal slew rate at DQ 42.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A random access memory (RAM) device comprising:
a memory array;
a level detector monitoring a source voltage and providing a level signal representative of a voltage range of the source voltage;
an off-chip driver (OCD) associated with the memory array and providing an output signal having at least one operating parameter, wherein the OCD adjusts the at least one operating parameter by adjusting a magnitude of at least one impedance based on the level signal.

2. The memory of claim 1, wherein the device is a dynamic random access device (DRAM).

3. The memory of claim 1, wherein each impedance of the plurality of impedances comprises a plurality of transistors.

4. The memory of claim 1, wherein the at least one operating parameter comprises a current.

5. The memory of claim 4, wherein the OCD further comprises:
a first impedance of the plurality of impedances comprising a plurality of transistors coupled in parallel between the output node and the source voltage; and
a second impedance of the plurality of impedances comprising a plurality of transistors coupled in parallel between the output node and a reference node.

6. The memory of claim 1, wherein the at least one operating parameter comprises a slew-rate.

7. The memory of claim 6, wherein the OCD further comprises:
a first transistor coupled between the output node and the source voltage and having a control gate;
a second transistor coupled between the output node and a reference node and having a control gate;
a first impedance of the plurality of impedances comprising a plurality of transistors coupled between the control gate of the first transistor and a power supply; and
a second impedance of the plurality of impedances comprising a plurality of transistors coupled between the control gate of the second transistor and a reference node.

8. A dynamic random access memory device comprising:
a memory array;
a level detector monitoring a source voltage and providing a level signal representative of a voltage range of the source voltage; and
an off-chip driver (OCD) associated with the memory array, the OCD receiving a data signal having a first and a second state and providing at an output node an output signal having a current level, wherein the OCD couples the output node to the source voltage via a first impedance when the data signal has the first state and to a reference node via a second impedance when the data signal has the second state, and wherein the OCD adjusts the current level by adjusting a magnitude of the first impedance and a magnitude of the second impedance based on the level signal.

9. The memory of claim 8, wherein the level signal comprises a low level signal and a high level signal, wherein the low level signal has a first state when the source voltage is less than the voltage range and second state when the source voltage is within the voltage range and the high level signal has a first state when the source voltage is greater than the voltage range and a second state when the source voltage is within the voltage range.

10. The memory of claim 9, wherein the OCD includes a logic block receiving the data signal and an enable signal having an active state, and providing a pull-up enable signal having an active state when the enable signal has the active state and the data signal has the first state, and providing a pull-down enable signal having an active state when the enable signal has the active state and the data signal has the second state.

11. The memory of claim 10, wherein the logic block comprises:
an AND-gate receiving the data signal at a first input and the enable signal at a second input, and providing the pull-up enable signal at an output;
an inverter receiving the enable signal at an input and having an output; and
an OR-gate receiving the data signal at a first input, coupled to the inverter output at a second input, and providing the pull-down enable signal at an output.

12. The memory of claim 10, wherein the OCD further comprises:
a pull-up circuit configured to couple the output node to the source voltage via the first impedance when the pull-up enable signal has the active state, and configured to increase the magnitude of the first impedance when the high level signal has the first state and to decrease the magnitude of the first impedance when the low level signal has the first state; and
a pull-down circuit configured to couple the output node to the source voltage via the second impedance when the pull-down enable signal has the active state, and configured to increase the magnitude of the second impedance when the high level signal has the first state and to decrease the magnitude of the second impedance when the low level signal has the first state.

13. The memory of claim 12, wherein the first impedance comprises a first plurality of transistors coupled in parallel between the source voltage and the output node and the second impedance comprises a second plurality of transistors coupled in parallel between the output node and the reference node, and wherein the pull-up and pull-down circuits adjust the magnitudes of the first and second impedances by turning on varying numbers of transistors based on the high and low level signals.

14. The memory of claim 13, wherein the pull-up circuit comprises
an first inverter receiving the second level signal at an input and having an output;
a first AND-gate receiving the pull-up enable signal at a first input, having a second input coupled to the output of the first inverter, and having an output;
a second AND-gate receiving the pull-up enable signal at a first input, the first level signal at a second input, and having an ouput;
a second inverter receiving the pull-up enable signal at an input and providing a first pull-up signal at an output;
a third inverter having an input coupled to the output of first AND-gate an providing a second pull-up signal at an output; and
a fourth inverter having an input coupled to the output of the second AND-gate and providing a third pull-up signal at an output.

15. The memory of 14, wherein the first impedance comprises:
a first PMOS transistor having a source coupled to the source voltage, a drain coupled to the output node; and a gate receiving the first pull-up signal;
a second PMOS transistor having a source coupled to the source voltage, a drain coupled to the output node; and a gate receiving the second pull-up signal;
a third PMOS transistor having a source coupled to the source voltage, a drain coupled to the output node; and a gate receiving the third pull-up signal.

16. The memory of 13, wherein the pull-down circuit comprises:
a first inverter receiving the first level signal at an input and having an output;
a first OR-gate receiving the pull-down enable signal at a first input, the second level signal at a second input, and having an output;
a second OR-gate receiving the pull-down enable signal at a first input, having a second input coupled to the output of the first inverter, and having an output;
a second inverter receiving the pull-down enable signal at an input and providing a first pull-down signal at an output;
a third inverter having an input coupled to the output of the first OR-gate and providing a second pull-down signal at an ouput; and
a further inverter having an input coupled to the output of the second OR-gate and providing a third pull-down signal at an output.

17. The memory of 16, wherein the second impedance comprises:
a first NMOS transistor having a drain coupled to the output node, a source coupled to a reference node, and a gate receiving the first pull-down signal;
a second NMOS transistor having a drain coupled to the output node, a source coupled to a reference node, and a gate receiving the second pull-down signal;
a third NMOS transistor having a drain coupled to the output node, a source coupled to a reference node, and a gate receiving the third pull-down signal.

18. A dynamic random access memory device (DRAM) comprising:
a memory array;
a level detector monitoring a source voltage and providing a level signal representative of a voltage range of the source voltage; and
an off-chip driver (OCD) associated with the memory array, the OCD receiving a data signal having a first and a second state and providing at an output node an output signal having a slew rate, wherein the OCD couples the source node to the source voltage via a first output switch having a control gate when the data signal has the first state and to a reference node via a second output switch having control gate when the data signal has the second state, and wherein the OCD adjusts the slew rate by adjusting a magnitude of a first impedance coupled between the control gate of the first output switch and a power supply and a magnitude of a second impedance coupled between the control gate of the second output switch and a reference node based on the level signal.

19. The memory of claim 18, wherein the level signal comprises a low level signal and a high level signal, wherein the low level signal has a first state when the source voltage is less than the voltage range and second state when the source voltage is within the voltage range and the high level signal has a first state when the source voltage is greater than the voltage range and a second state when the source voltage is within the voltage range.

20. The memory of claim 19, wherein the OCD includes a logic block receiving the data signal and an enable signal having an active state, and providing a pull-up enable signal having an active state when the enable signal has the active state and the data signal has the first state, and providing a pull-down enable signal having an active state when the enable signal has the active state and the data signal has the second state.

21. The memory of claim 20, wherein the logic block comprises:
an AND-gate receiving the data signal at a first input and the enable signal at a second input, and providing the pull-up enable signal at an output;
an inverter receiving the enable signal at an input and having an output; and
an OR-gate receiving the data signal at a first input, coupled to the inverter output at a second input, and providing the pull-down enable signal at an output.

22. The memory of claim 20, wherein the OCD further comprises:
a pull-up circuit configured to turn-on the first output switch when the pull-up enable signal has the active state, and configured to increase the magnitude of the first impedance when the high level signal has the first state and to decrease the magnitude of the first impedance when the low level signal has the first state; and
a pull-down circuit configured to turn-on the second output switch when the pull-down enable signal has the active state, and configured to increase the magnitude of the second impedance when the high level signal has the first state and to decrease the magnitude of the second impedance when the low level signal has the first state.

23. The memory of claim 22, wherein the first impedance comprises a first plurality of transistors coupled between the control of the first output switch and the power supply and the second impedance comprises a second plurality of transistors coupled in between the control gate of the second-output switch and the reference node, and wherein the pull-up and pull-down circuits adjust the magnitudes of the first and second impedances by turning on varying numbers of transistors based on the high and low level signals.

24. The memory of claim 23, wherein the first switch comprises a PMOS switch having the control gate, a source coupled to the source voltage, and a drain coupled to the output node, and the second switch comprises an NMOS switch having the control gate, a source coupled to the reference node, and a drain coupled to the output node.

25. The memory of claim 24, wherein the pull-up circuit comprises:
a first inverter receiving the pull-up enable signal at an input and providing a pull-up signal at an output;
a second inverter receiving the second level signal at an input and having an output; and
the first impedance, the first impedance comprising:
a first NMOS transistor having a gate receiving the pull-up enable signal, a drain coupled to the output of the first inverter, and having a source;
a second NMOS transistor having a gate receiving the pull-up enable signal, a drain coupled to the output of the first inverter, and having a source;
a third NMOS transistor having a gate coupled to the output of the second inverter, a drain coupled to the source of the first NMOS transistor, and a source coupled to a reference node; and
a fourth NMOS transistor having a gate receiving the first level signal, a drain coupled to the source of the second NMOS transistor, and a source coupled to the reference node.

26. The memory of claim 24, wherein the pull-down circuit comprises:
a first inverter receiving the pull-down enable signal at an input and providing a pull down signal at an output;
a second inverter receiving the first level signal at an input and having an output; and
the second impedance, the second impedance comprising:
a first PMOS transistor having a gate coupled to the output of the second inverter, a source coupled to the source voltage; and having a drain;
a second PMOS transistor having a gate receiving the second level signal, a source coupled to the source voltage, and having a drain;
a third PMOS transistor having a gate receiving the pull-down enable signal, a source coupled to the drain of the first PMOS transistor, and a drain coupled to the output of the first inverter; and
a fourth PMOS transistor having a gate receiving the pull-down enable signal, a source coupled to the drain of the second PMOS transistor, and a drain coupled to the output of the output of the first inverter.

27. A method of adjusting a current level of an output signal of an off-chip driver in a dynamic random access memory device, the method comprising:
providing a level signal representative of a voltage range of a source voltage;
receiving a data signal having a first state and a second state;
providing the output signal at an output node by coupling the output node to the source voltage via a first impedance when the data signal has the first state and to a reference node via a second impedance when the data signal has the second state; and
varying a magnitude of the first impedance and a magnitude to the second impedance based on the level signal.

28. A method of adjusting a slew rate of an output signal of an off-chip driver in a dynamic random access memory device, the method comprising:
providing a level signal representative of a voltage range of a source voltage;
receiving a data signal having a first state and a second state;
providing the output signal at an output node by coupling the output node to the source voltage via a first switch having a control gate when the data signal has the first state and by coupling the output node to a reference node via a second switch having a control gate when the data has the second state;
providing a first impedance between the control gate of the first switch and a power supply and a second impedance between the control gate of the second switch and a reference node; and
varying a magnitude of the first impedance and a magnitude of the second impedance based on the level signal.
